(19) United States
(12) Patent Application Publication
(10) Pub. No.: US 2024/0322830 A1
(43) Pub. Date: Sep. 26, 2024

(54) PHASE-LOCKED LOOP (PLL) WITH AUTOMATIC LOOP BANDWIDTH CONTROL

(71) Applicant: QUALCOMM Incorporated, San Diego, CA (US)

(72) Inventor: Alessio SANTICCIOLI, San Diego, CA (US)

(21) Appl. No.: 18/186,559

(22) Filed: Mar. 20, 2023

(51) Int. Cl. H03L 7/107; H03L 7/093; H03L 7/10

(52) U.S. Cl. CPC H03L 7/1075; H03L 7/093; H03L 7/102; H03L 7/18

(57) ABSTRACT

Certain aspects of the present disclosure generally relate to techniques and apparatus for jitter detection using time-based and/or voltage-based techniques. An example jitter detection circuit generally includes: a comparator having a first input coupled to an input of the jitter detection circuit; a first combiner having an input coupled to an output of the comparator; an accumulator having an input coupled to an output of the first combiner, an output of the accumulator being coupled to an output of the jitter detection circuit; and a digital-to-analog converter (DAC) having an input coupled to the output of the accumulator, an output of the DAC being coupled to a second input of the comparator.

### BACKGROUND

### Field of the Disclosure

Certain aspects of the present disclosure generally relate to electronic components and, more particularly, to phase-locked loops.

### Description of Related Art

Electronic devices include computing devices such as desktop computers, notebook computers, tablet computers, smartphones, wearable devices like a smartwatch, internet servers, and so forth. These various electronic devices provide information, entertainment, social interaction, security, safety, productivity, transportation, manufacturing, and other services to human users. These various electronic devices depend on wireless communications for many of their functions. Wireless communication systems and devices are widely deployed to provide various types of communication content such as voice, video, packet data, messaging, broadcast, and so on. These systems may be capable of supporting communication with multiple users by sharing the available system resources (e.g., time, frequency, and power). Examples of such systems include code division multiple access (CDMA) systems, time division multiple access (TDMA) systems, frequency division multiple access (FDMA) systems, and orthogonal frequency division multiple access (OFDMA) systems (e.g., a Long Term Evolution (LTE) system or a New Radio (NR) system). Wireless devices may include a transceiver for processing signals for reception or transmission. A transmitter and receiver may include one or more oscillators and one or more amplifiers. In some implementations, the one or more oscillators may include a phase-locked loop with a voltage-controlled oscillator (VCO) for generating an oscillating signal, which may be used for signal processing during signal transmission and reception.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide the advantages described herein.

Certain aspects of the present disclosure are directed towards a jitter detection circuit. The jitter detection circuit generally includes: a comparator having a first input coupled to an input of the jitter detection circuit; a first combiner having an input coupled to an output of the comparator; an accumulator having an input coupled to an output of the first combiner, an output of the accumulator being coupled to an output of the jitter detection circuit; and a digital-to-analog converter (DAC) having an input coupled to the output of the accumulator, an output of the DAC being coupled to a second input of the comparator.

Certain aspects of the present disclosure are directed towards a jitter detection circuit. The jitter detection circuit generally includes: a first digital-to-time converter (DTC); a second DTC; a PD having a first input coupled to an output of the first DTC and a second input coupled to an output of the second DTC; a first combiner having an input coupled to an output of the PD; and an accumulator having an input coupled to an output of the combiner, wherein an output of the accumulator is coupled to a first input of the first DTC and to a first input of the second DTC.

Certain aspects of the present disclosure are directed towards a method for signal processing. The method generally includes: comparing, via a comparator, a PD output voltage and an analog jitter detection signal to yield a comparator output signal; subtracting, via a first combiner, a digital signal from the comparator output signal; accumulating, via an accumulator, an output signal from the first combiner to generate a first jitter detection signal; and generating, via a DAC, the analog jitter detection signal based on the first jitter detection signal.

Certain aspects of the present disclosure are directed towards a method for signal processing. The method generally includes: generating, via a first DTC, a first time-domain signal based on a reference signal and a first jitter detection signal; generating, via a second DTC, a second time domain signal based on an oscillating signal and the first jitter detection signal; generating, via a PD, a PD signal indicating a phase difference between the first time-domain signal and the second time-domain signal; subtracting, via a first combiner, a digital signal from the PD signal to generate a combiner signal; and generating, via an accumulator, the first jitter detection signal based on the combiner signal.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain aspects of this disclosure and are therefore not to be considered limiting of its scope, for the description may admit to other equally effective aspects.

FIG. 1 is a diagram of an example wireless communications network, in which

aspects of the present disclosure may be practiced.

FIG. 2 is a block diagram of an example access point (AP) and example user terminals, in which aspects of the present disclosure may be practiced.

FIG. 3 is a block diagram of an example transceiver front end, in which aspects of the present disclosure may be practiced.

FIG. 4 illustrates an example phase-locked loop (PLL), in accordance with certain aspects of the present disclosure.

FIG. 5 illustrates a jitter detection circuit using voltage-based techniques, in accordance with certain aspects of the present disclosure.

FIG. 6 is a graph showing a probability density function of a phase detection voltage, in accordance with certain aspects of the present disclosure.

FIG. 7 illustrates a jitter detection circuit using time-based techniques, in accordance with certain aspects of the present disclosure.

FIGS. 8 and 9 illustrate multiple parallel jitter detection circuits, in accordance with certain aspects of the present disclosure.

FIG. 10 is a flow diagram depicting example operations for signal processing including jitter detection using voltage-based techniques, in accordance with certain aspects of the present disclosure.

FIG. 11 is a flow diagram depicting example operations for signal processing including jitter detection using time-based techniques, in accordance with certain aspects of the present disclosure

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure are directed towards apparatus and techniques for automatic loop bandwidth adjustment to reduce (e.g., minimize) phase-locked loop (PLL) output jitter (and integrated phase noise (IPN)). Some aspects provide a jitter detection circuit implemented with suitably high resolution for more accurate jitter detection compared to at least some conventional implementations. The jitter detection circuit may be implemented with a voltage-based or time-based jitter detection circuit, as described in more detail herein.

### Example Wireless Communications

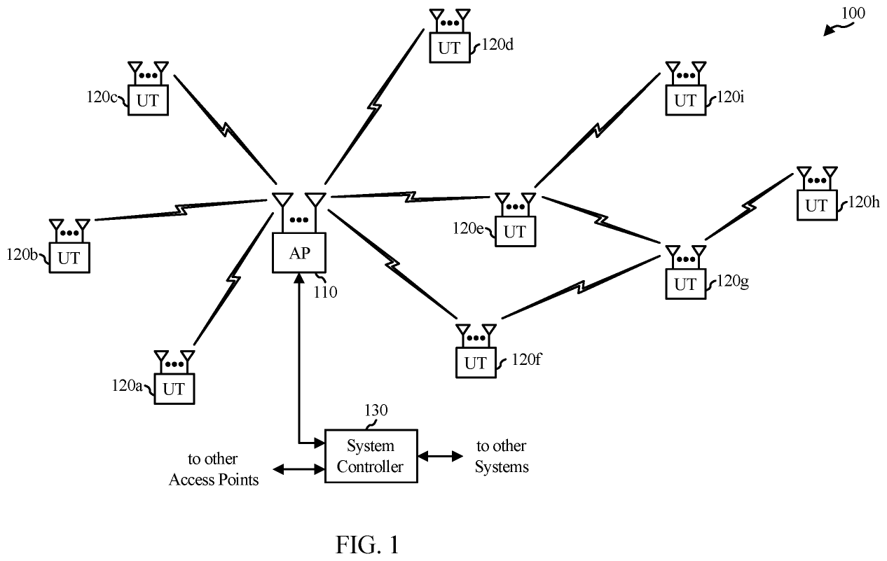

FIG. 1 illustrates a wireless communications system 100 with access points 110 and user terminals 120, in which aspects of the present disclosure may be practiced. For simplicity, only one access point 110 is shown in FIG. 1. An access point (AP) is generally a fixed station that communicates with the user terminals and may also be referred to as a base station (BS), an evolved Node B (eNB), a next generation Node B (gNB), or some other terminology. A user terminal (UT) may be fixed or mobile and may also be referred to as a mobile station (MS), an access terminal, user equipment (UE), a station (STA), a client, a wireless device, or some other terminology. A user terminal may be a wireless device, such as a cellular phone, a personal digital assistant (PDA), a handheld device, a wireless modem, a laptop computer, a tablet, a personal computer, etc.

Access point 110 may communicate with one or more user terminals 120 at any given moment on the downlink and uplink. The downlink (i.e., forward link) is the communication link from the access point to the user terminals, and the uplink (i.e., reverse link) is the communication link from the user terminals to the access point. A user terminal may also communicate peer-to-peer with another user terminal. A system controller 130 couples to and provides coordination and control for the access points.

Wireless communications system 100 employs multiple transmit and multiple receive antennas for data transmission on the downlink and uplink. Access point 110 may be equipped with a number Nₐₚ of antennas to achieve transmit diversity for downlink transmissions and/or receive diversity for uplink transmissions. A set Nᵤ of selected user terminals 120 may receive downlink transmissions and transmit uplink transmissions. Each selected user terminal transmits user-specific data to and/or receives user-specific data from the access point. In general, each selected user terminal may be equipped with one or multiple antennas (i.e., Nᵤₜ≥1). The Nᵤ selected user terminals can have the same or different number of antennas.

Wireless communications system 100 may be a time division duplex (TDD) system or a frequency division duplex (FDD) system. For a TDD system, the downlink and uplink share the same frequency band. For an FDD system, the downlink and uplink use different frequency bands. Wireless communications system 100 may also utilize a single carrier or multiple carriers for transmission. Each user terminal 120 may be equipped with a single antenna (e.g., to keep costs down) or multiple antennas (e.g., where the additional cost can be supported). In some aspects, the user terminal 120 or access point 110 may include a frequency synthesizer implemented using a phase-locked loop (PLL) having circuitry for automatic jitter detection and loop bandwidth control, as described in more detail herein.

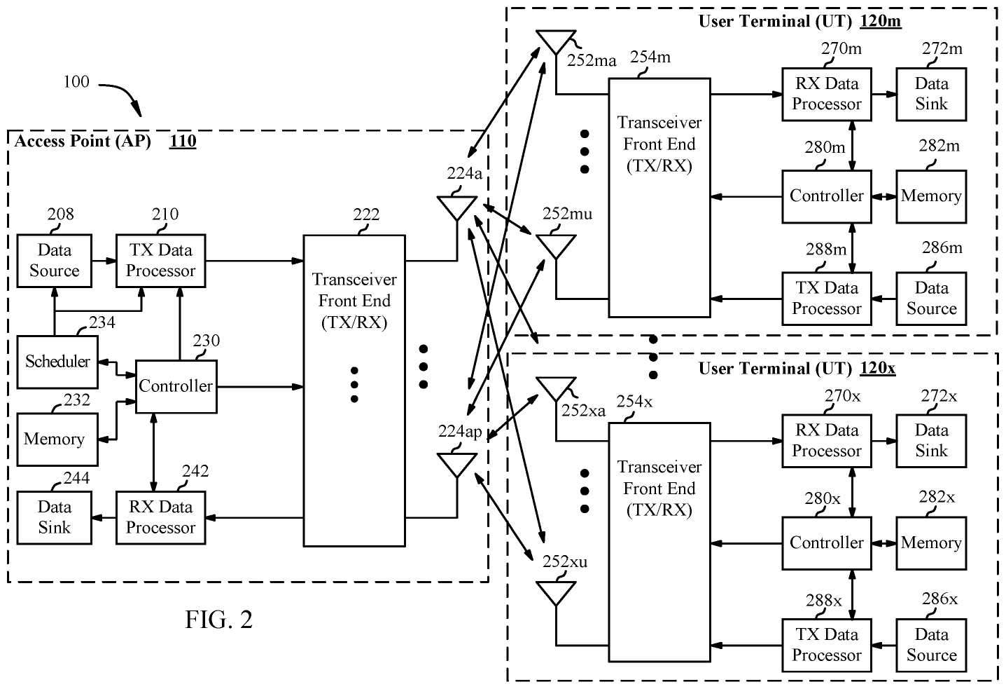

FIG. 2 shows a block diagram of access point 110 and two user terminals 120m and 120x in the wireless communications system 100. Access point 110 is equipped with Nₐₚ antennas 224a through 224ap. User terminal 120m is equipped with N_{ut,m} antennas 252ma through 252mu, and user terminal 120x is equipped with N_{ut,x} antennas 252xa through 252xu. Access point 110 is a transmitting entity for the downlink and a receiving entity for the uplink. Each user terminal 120 is a transmitting entity for the uplink and a receiving entity for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink, Nᵤₚ user terminals are selected for simultaneous transmission on the uplink, N_{dn} user terminals are selected for simultaneous transmission on the downlink. Nᵤₚ may or may not be equal to N_{dn}, and Nᵤₚ and N_{dn} may be static values or can change for each scheduling interval. Beam-steering, beamforming, or some other spatial processing technique may be used at the access point and/or user terminal.

On the uplink, at each user terminal 120 selected for uplink transmission, a TX data processor 288 receives traffic data from a data source 286 and control data from a controller 280. TX data processor 288 processes (e.g., encodes, interleaves, and modulates) the traffic data {dᵤₚ} for the user terminal based on the coding and modulation schemes associated with the rate selected for the user terminal and provides a data symbol stream {sᵤₚ} for one of the N_{ut,m} antennas. A transceiver front end (TX/RX) 254 (also known as a radio frequency front end (RFFE)) receives and processes (e.g., converts to analog, amplifies, filters, and frequency upconverts) a respective symbol stream to generate an uplink signal. The transceiver front end 254 may also route the uplink signal to one of the N_{ut,m} antennas for transmit diversity via an RF switch, for example. The controller 280 may control the routing within the transceiver front end 254. Memory 282 may store data and program codes for the user terminal 120 and may interface with the controller 280.

A number Nᵤₚ of user terminals 120 may be scheduled for simultaneous transmission on the uplink. Each of these user terminals transmits its set of processed symbol streams on the uplink to the access point.

At access point 110, Nₐₚ antennas 224a through 224ap receive the uplink signals from all Nᵤₚ user terminals transmitting on the uplink. For receive diversity, a transceiver front end 222 may select signals received from one of the antennas 224 for processing. The signals received from multiple antennas 224 may be combined for enhanced receive diversity. The access point's transceiver front end 222 also performs processing complementary to that performed by the user terminal's transceiver front end 254 and provides a recovered uplink data symbol stream. The recovered uplink data symbol stream is an estimate of a data symbol stream {sᵤₚ} transmitted by a user terminal. An RX data processor 242 processes (e.g., demodulates, deinterleaves, and decodes) the recovered uplink data symbol stream in accordance with the rate used for that stream to obtain decoded data. Decoded data for each user terminal or access terminal may be provided to a data sink (e.g., data sink 244, data sink 272m, or data sink 272x) for storage and/or a controller for further processing.

On the downlink, at access point 110, a TX data processor 210 receives traffic data from a data source 208 for N_{dn} user terminals scheduled for downlink transmission, control data from a controller 230 and possibly other data from a scheduler 234. The various types of data may be sent on different transport channels. TX data processor 210 processes (e.g., encodes, interleaves, and modulates) the traffic data for each user terminal based on the rate selected for that user terminal. TX data processor 210 may provide a downlink data symbol streams for one of more of the N_{dn} user terminals to be transmitted from one of the Nₐₚ antennas. The transceiver front end 222 receives and processes (e.g., converts to analog, amplifies, filters, and frequency upconverts) the symbol stream to generate a downlink signal. The transceiver front end 222 may also route the downlink signal to one or more of the Nₐₚ antennas 224 for transmit diversity via an RF switch, for example. The controller 230 may control the routing within the transceiver front end 222. Memory 232 may store data and program codes for the access point 110 and may interface with the controller 230.

At each user terminal 120, N_{ut,m} antennas 252 receive the downlink signals from access point 110. For receive diversity at the user terminal 120, the transceiver front end 254 may select signals received from one or more of the antennas 252 for processing. The signals received from multiple antennas 252 may be combined for enhanced receive diversity. The user terminal's transceiver front end 254 also performs processing complementary to that performed by the access point's transceiver front end 222 and provides a recovered downlink data symbol stream. An RX data processor 270 processes (e.g., demodulates, deinterleaves, and decodes) the recovered downlink data symbol stream to obtain decoded data for the user terminal. In some aspects, the transceiver front end 254 or 222 may include a frequency synthesizer implemented using a PLL having circuitry for automatic jitter detection and loop bandwidth control, as described in more detail herein.

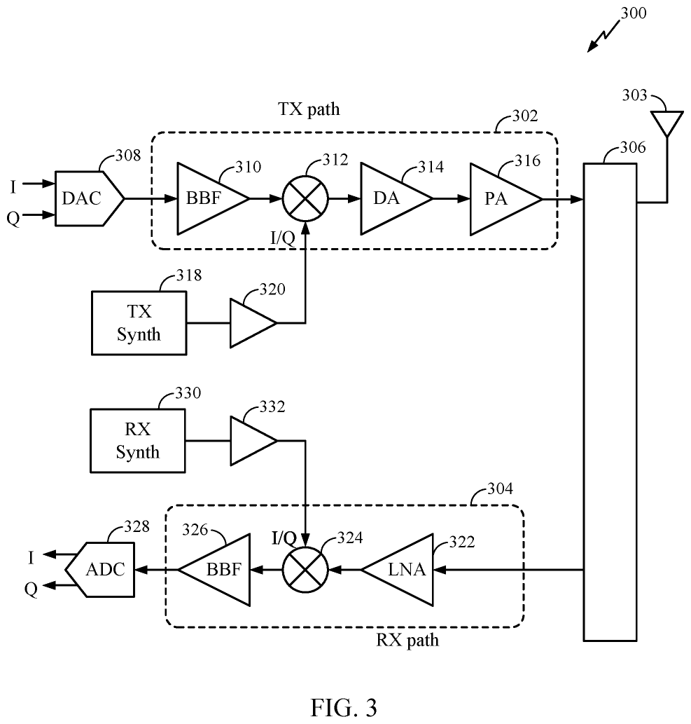

FIG. 3 is a block diagram of an example transceiver front end 300, such as transceiver front ends 222, 254 in FIG. 2, in which aspects of the present disclosure may be practiced. The transceiver front end 300 includes a transmit (TX) path 302 (also known as a “transmit chain”) for transmitting signals via one or more antennas and a receive (RX) path 304 (also known as a “receive chain”) for receiving signals via the antennas. When the TX path 302 and the RX path 304 share an antenna 303, the paths may be connected with the antenna via an interface 306, which may include any of various suitable radio frequency (RF) devices, such as a switch, a duplexer, a diplexer, a multiplexer, and the like.

Receiving in-phase (I) or quadrature (Q) baseband analog signals from a digital-to-analog converter (DAC) 308, the TX path 302 may include a baseband filter (BBF) 310, a mixer 312, a driver amplifier (DA) 314, and a power amplifier (PA) 316. The BBF 310, the mixer 312, and the DA 314 may be included in a radio frequency integrated circuit (RFIC). In some cases, the PA 316 may be external to the RFIC.

The BBF 310 filters the baseband signals received from the DAC 308, and the mixer 312 mixes the filtered baseband signals with a transmit local oscillator (LO) signal to convert the baseband signal of interest to a different frequency (e.g., upconvert from baseband to RF). This frequency-conversion process produces the sum and difference frequencies of the LO frequency and the frequency of the signal of interest. The sum and difference frequencies are referred to as the “beat frequencies.” The beat frequencies are typically in the RF range, such that the signals output by the mixer 312 are typically RF signals, which may be amplified by the DA 314 and/or by the PA 316 before transmission by the antenna 303. While one mixer 312 is illustrated, several mixers may be used to upconvert the filtered baseband signals to one or more intermediate frequencies and to thereafter upconvert the intermediate frequency (IF) signals to a frequency for transmission.

The RX path 304 includes a low noise amplifier (LNA) 322, a mixer 324, and a baseband filter (BBF) 326. The LNA 322, the mixer 324, and the BBF 326 may be included in a radio frequency integrated circuit (RFIC), which may or may not be the same RFIC that includes the TX path components. RF signals received via the antenna 303 may be amplified by the LNA 322, and the mixer 324 mixes the amplified RF signals with a received local oscillator (LO) signal to convert the RF signal of interest to a different baseband frequency (i.e., downconvert). The baseband signals output by the mixer 324 may be filtered by the BBF 326 before being converted by an analog-to-digital converter (ADC) 328 to digital I or Q signals for digital signal processing.

Certain transceivers may employ frequency synthesizers with a variable-frequency oscillator (e.g., a voltage-controlled oscillator (VCO) or a digitally controlled oscillator (DCO)) to generate a stable, tunable LO with a particular tuning range. Thus, the transmit LO frequency may be produced by a TX frequency synthesizer 318, which may be buffered or amplified by amplifier 320 before being mixed with the baseband signals in the mixer 312. Similarly, the receive LO frequency may be produced by an RX frequency synthesizer 330, which may be buffered or amplified by amplifier 332 before being mixed with the RF signals in the mixer 324. In some cases, a single frequency synthesizer may be used for both the TX path 302 and the RX path 304. In some aspects, the RX frequency synthesizer 330 and/or the TX frequency synthesizer 318 may include a PLL having circuitry for automatic jitter detection and loop bandwidth control, as described in more detail herein.

While FIGS. 1-3 provide wireless communications as an example application in which certain aspects of the present disclosure may be implemented to facilitate understanding, certain aspects described herein may be used for PLLs in any of various other suitable systems (e.g., video monitors, microprocessors, high-speed serializer/deserializer (SerDes) systems, or other electronic systems).

### Example Phase-Locked Loop

Phase-locked loop (PLL) output jitter and integrated phase noise (IPN) depend on the loop bandwidth settings of the PLL. Conventionally, costly and lengthy testing may be used to tune each individual band across process, voltage, and temperature (PVT). Certain aspects of the present disclosure are directed toward the detection of PLL output jitter/IPN for automatic bandwidth tuning. Using automatic bandwidth tuning reduces testing time and may provide noise information that can be used for automated part screening.

At least some jitter detection implementations may be unsuitable for ultra-low jitter PLLs (e.g., below 100 fs jitter for Fifth-Generation (5G) applications) due to the limited achievable resolution (e.g., down to 10 ps), which prevents accurate jitter detection in such PLLs. Some aspects of the present disclosure are directed to circuitry for voltage-based indirect jitter detection, which may use a comparator, a digital accumulator, and a narrow-range digital-to-analog converter (DAC). Other aspects of the present disclosure are directed to circuitry for time-based indirect jitter detection, which may use a phase detector, a digital accumulator, and narrow-range digital-to-time converters (DTCs). Both the voltage-based and time-based jitter detection circuits provide better resolution and lower power consumption and area as compared to at least some conventional implementations. A controller may be used to automatically set the loop bandwidth of the PLL according to the jitter detector output in an attempt to reduce (e.g., minimize) jitter.

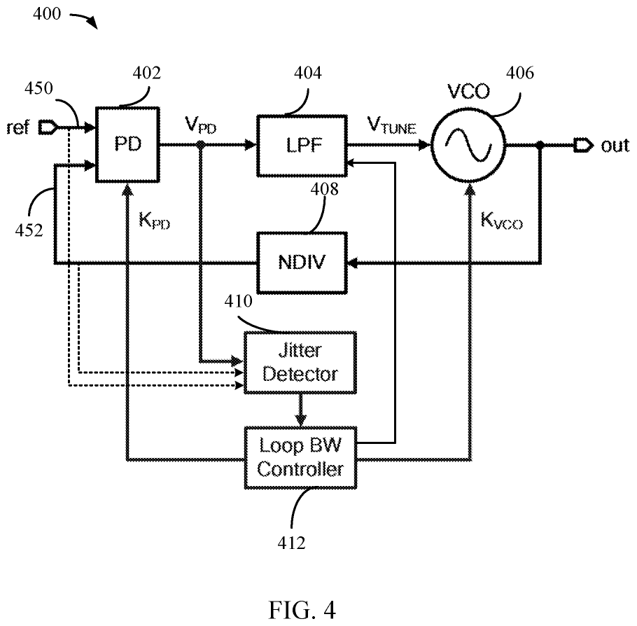

FIG. 4 illustrates an example PLL, in accordance with certain aspects of the present disclosure. As shown, the PLL includes a VCO 406 providing a tunable oscillating signal (e.g., at output labeled “out”). The oscillating signal may be fed back to a phase detector (PD) 402. In some aspects, a frequency divider 408 may be used to generate a frequency-divided version of the oscillating signal. The frequency-divided oscillating signal 452 may be provided to the PD 402. The PD compares the frequency-divided oscillating signal 452 to a reference signal 450 (labeled “ref”), which may be generated by a reference oscillator (e.g., a crystal oscillator), and generates a PD voltage (V_{PD}) that represents the phase difference between the frequency-divided oscillating signal 452 and the reference signal 450. V_{PD} is provided to a low-pass filter 404 to yield a filtered PD voltage, which is used as a tuning voltage (VTUNE) for controlling the VCO 406.

In some aspects, the PLL 400 includes a jitter detection circuit 410 and a loop bandwidth (BW) controller 412. The jitter detection circuit 410 generates a jitter detection signal indicating the jitter associated with the PLL. Jitter is a measure of the deviation of actual PLL clock edges from reference clock edges (e.g., from clock edges of the reference signal 450). In some aspects, the jitter detection may be based on the PD voltage at the output of the PD 402 using voltage-based techniques. In other aspects, the jitter detection may be based on the reference signal 450 and the frequency-divided oscillating signal 452 using time-based techniques.

The jitter detection signal is provided to the loop BW controller 412 that adjusts the PLL parameters to reduce the jitter. For example, the loop BW controller 412 may adjust a gain of the PD 402 (e.g., by setting a gain coefficient K_{PD}) and/or a gain of the VCO 406 (e.g., by setting a gain coefficient K_{VCO}) and/or the transfer function of the low-pass filter 404 (e.g., by setting values of poles, zeros, and/or gain for the filter 404).

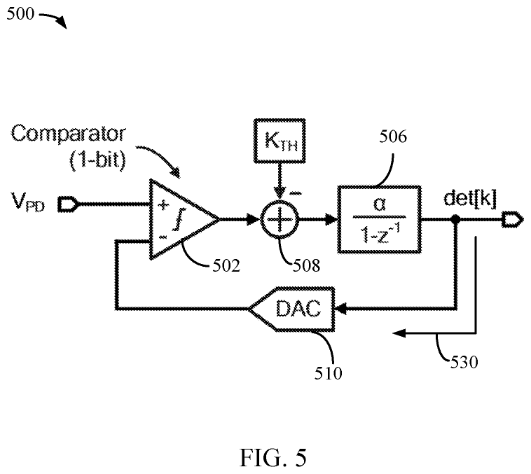

FIG. 5 illustrates a jitter detection circuit 500 (e.g., corresponding to jitter detection circuit 410) using voltage-based techniques, in accordance with certain aspects of the present disclosure. The jitter detection circuit 500 includes a comparator 502 having a positive terminal receiving V_{PD} and a negative terminal receiving an analog signal from a digital-to-analog converter (DAC) 510. The output of the comparator 502 may be coupled to a digital accumulator 506 for generating the jitter detection signal (e.g., digital signal labeled “det[k]”) indicating the jitter associated with the PLL. The jitter detection signal may be provided to the DAC 510 for conversion to a jitter detection analog signal. The jitter detection analog signal may be provided to the negative terminal of the comparator 502 for comparison with V_{PD}. Due to the narrow range associated with jitter, the DAC 510 may be implemented with narrow range, allowing for low power and area consumption by the DAC.

The comparator 502 may output a logic high (e.g., +1) if V_{PD} is greater than the jitter detection analog signal or a logic low (e.g., −1) if V_{PD} is less than the jitter detection analog signal. If the accumulator 506 receives a logic high input, the accumulator increases the jitter detection signal, and if the accumulator 506 receives a logic low input, the accumulator decreases the jitter detection signal.

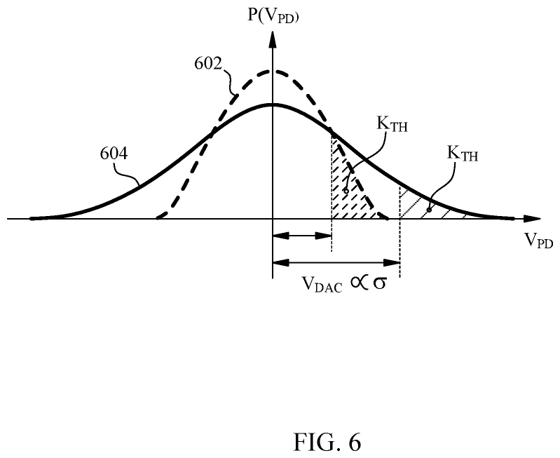

FIG. 6 is a graph showing the probability density function of V_{PD}, in accordance with certain aspects of the present disclosure. As shown, curve 602 shows the probability density function of V_{PD} for low jitter, and curve 604 shows the probability density function of V_{PD} for high jitter. As shown, the probability density functions are centered on zero. Thus, without a combiner 508 (e.g., with a direct connection between the output of the comparator 502 and the input of the accumulator 506), the comparator 502 may output an equal number of logic highs and logic lows. The accumulator 506 effectively provides an average of the digital signals input to the accumulator 506. Therefore, with the comparator 502 outputting an equal number of logic highs and logic lows, the jitter detection signal generated by the accumulator may average to zero (e.g., as opposed to a value representing jitter).

In some aspects, the effective threshold of comparator 502 may be shifted so that the comparator 502 outputs a greater number of logic highs than logic lows. Referring back to FIG. 5, the combiner 508 may be coupled between the output of the comparator 502 and the input of the digital accumulator 506. The combiner 508 may subtract a fractional threshold value (K_{TH}) from the digital signal generated by the comparator 502 to yield an input signal (e.g., a multi-bit signal) to the digital accumulator 506. With the combiner 508, the effective threshold of the comparator 502 may be shifted by subtracting K_{TH} as described. Due to the negative feedback loop 530, the jitter detection signal output by the accumulator 506 effectively sets the average of the digital signal output by the comparator 502 to be equal to K_{TH} (e.g., the fraction of logic highs output by the comparator 502 with respect to logic lows corresponds to K_{TH}). By subtracting K_{TH}, the comparator 502 outputs a greater number of logic highs than logic lows due to the comparator threshold being reduced (e.g., the analog signal output by the DAC 510 being reduced due to the subtraction of K_{TH}). Thus, the comparator 502 operates at a percentile of the probability density function (e.g., associated with curve 604 shown in FIG. 6) that is dependent on K_{TH}. V_{DAC} (and det[k]) are proportional to the standard deviation (σ) of the jitter associated with the PLL (e.g., VDAC and det[k]∝σ). As shown in FIG. 6, K_{TH} may be set based on an expected range of PLL jitter and DAC resolution. K_{TH} effectively sets the jitter detection probability threshold associated with the jitter detection circuit. The accumulator 506 generates a digital output (e.g., jitter detection signal) that may be proportional to the standard deviation of the PLL jitter.

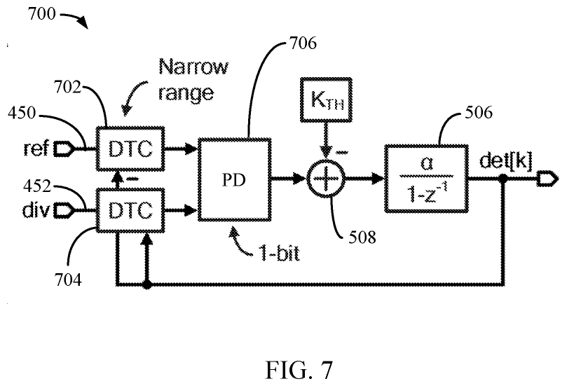

FIG. 7 illustrates a jitter detection circuit 700 using time-based techniques, in accordance with certain aspects of the present disclosure. As shown, the jitter detection circuit 700 may include a digital-to-time converter (DTC) 702 receiving the reference signal 450 and a DTC 704 receiving the frequency-divided oscillating signal 452. As shown, DTC 702 and DTC 704 also receive the jitter detection signal from the accumulator 506. DTC 702 may generate a time-domain signal based on the reference signal 450 and the jitter detection signal from the accumulator 506. For example, DTC 702 may delay the reference signal 450 by an amount proportional to a changed-sign version of the digital jitter detection signal from the accumulator 506. Similarly, DTC 704 may generate a time-domain signal based on the frequency-divided oscillating signal 452 and the jitter detection signal. For example, DTC 704 may delay the frequency-divided oscillating signal 452 by an amount proportional to the digital jitter detection signal from the accumulator 506. Thus, DTCs 702, 704 generate two phase-shifted time-domain signals that may be provided to a PD 706 (e.g., a 1-bit PD, which may be implemented as a bang-bang PD (BBPD)).

The PD 706 may output a logic high (e.g., +1) if the phase of the time-domain signal from DTC 702 is greater than the phase of the time-domain signal from DTC 704, or may output a logic low (e.g., −1) if the phase of the time-domain signal from DTC 702 is less than the phase of the time-domain signal from DTC 704. The output of the PD 706 may be coupled to a combiner 508 for subtracting K_{TH} to generate an input signal to the accumulator 506. K_{TH} may be set based on an expected range of PLL jitter and DTC resolution. The accumulator 506 generates the jitter detection signal, as described herein. Due to the narrow range associated with jitter, DTC 702 and DTC 704 may be implemented with narrow range, allowing for low power and area consumption by the DTCs.

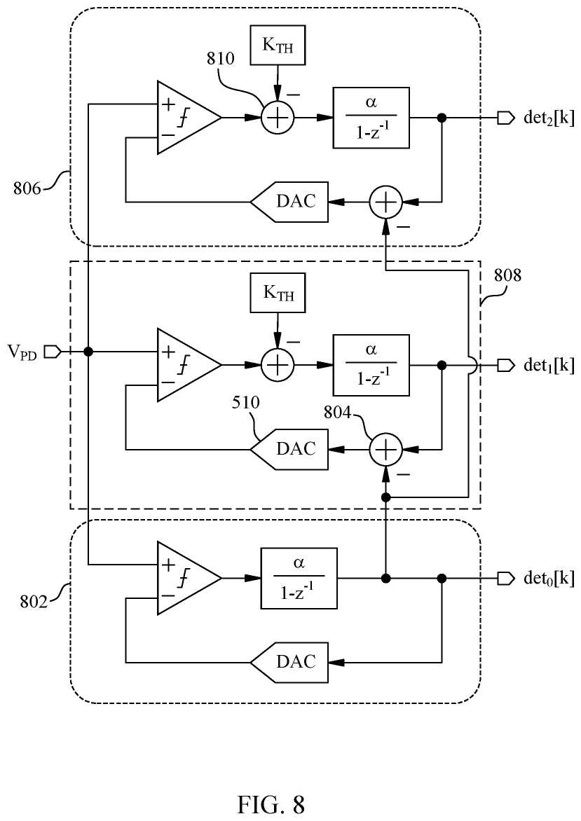

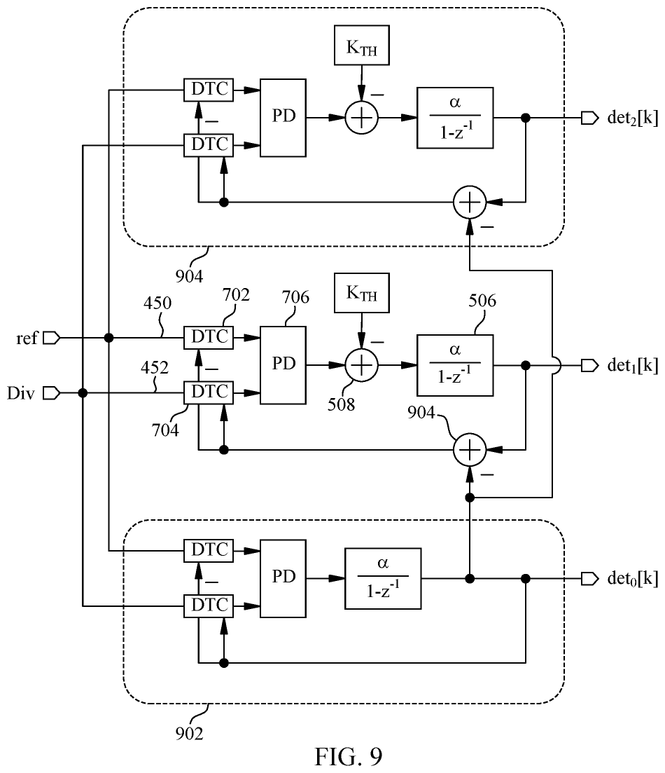

In certain aspects, multiple jitter detection circuits may operate in concert. In such cases, an output of one of the jitter detection circuits may be combined in the feedback loops of the other jitter detection circuits. FIGS. 8 and 9 illustrate multiple parallel jitter detection circuits, in accordance with certain aspects of the present disclosure.

As shown in FIG. 8, a first jitter detection circuit 802 may generate a jitter detection signal (det₀[k]) that may be provided to a second jitter detection circuit 808. Jitter detection circuit 802 may be similar to the jitter detection circuit 500 described with respect to FIG. 5, but implemented without the combiner 508.

Jitter detection circuit 808 generates a jitter detection signal (det₁[k]). Jitter detection circuit 808 may include a combiner 804 that subtracts det₀[k] from det₁[k] to generate the digital input signal to DAC 510, which is processed as described herein with respect to FIG. 5. As shown, jitter detection circuit 808 may include a combiner for subtracting K_{TH}, as described herein.

Det₀[k] may also be provided to a third jitter detection circuit 806 for generating a jitter detection signal (det₂[k]) in a similar manner. Jitter detection circuit 806 operates similarly to jitter detection circuit 808, but with a combiner 810 that subtracts K′_{TH}, where K′_{TH} is different than K_{TH}. By using multiple jitter detection circuits as described, the resolution and/or speed associated with jitter detection may be enhanced (e.g., allowing for efficient detection of different levels of jitter). While three jitter detection circuits are illustrated, any suitable number of jitter detection circuits may be coupled together (e.g., two or more jitter detection circuits). The jitter detection circuit 802 (e.g., associated with K_{TH} of zero) may cancel (or at least reduce) time-varying offsets associated with V_{PD}.

Moreover, as shown in FIG. 9, jitter detection circuits implemented using time-domain analysis may also be operated in concert with parallel loops. For example, jitter detection circuit 902 may generate det⁰[k] based on the reference signal 450 and oscillating signal 452, which may be subtracted from det¹[k] via combiner 904 and fed back to DTC 702 and DTC 704 for processing as described with respect to FIG. 7. Det₀[k] may also be provided to a jitter detection circuit 904 for generating a jitter detection signal (det₂[k]) in a similar manner.

For certain aspects, jitter detection circuits implemented using time-domain analysis and jitter detection circuits implemented using voltage-domain analysis may operate in concert.

### Example Signal Processing Operations

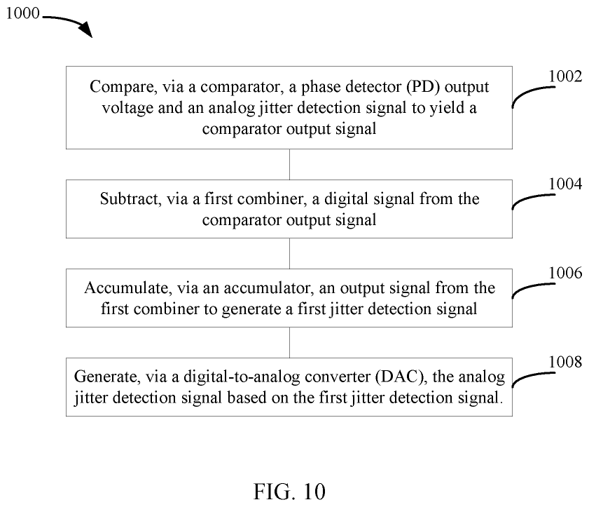

FIG. 10 is a flow diagram depicting example operations 1000 for signal processing, in accordance with certain aspects of the present disclosure. For example, the operations 1000 may be performed by a signal processing circuit, such as the jitter detection circuit 500, and in some aspects, the PLL 400.

The operations 1000 begin, at block 1002, with the signal processing circuit comparing, via a comparator, a phase detector (PD) output voltage and an analog jitter detection signal to yield a comparator output signal. The PD output voltage may represent a difference between a phase of a reference signal (e.g., reference signal 450) and a phase of an oscillating signal (e.g., oscillating signal 452).

At block 1004, the signal processing circuit subtracts, via a first combiner (e.g., combiner 508), a digital signal from the comparator output signal. The digital signal subtracted from the comparator output signal may be a fractional digital value. At block 1006, the signal processing circuit accumulates, via an accumulator (e.g., accumulator 506), an output signal from the first combiner to generate a first jitter detection signal. At block 1008, the signal processing circuit generates, via a DAC (e.g., DAC 510), the analog jitter detection signal based on the first jitter detection signal. In some aspects, the PLL controls at least one of a gain associated with a PD of the PLL or a gain associated with an oscillator of the PLL or the transfer function associated with a low-pass filter of the PLL, based on the jitter detection signal. For example, the loop BW controller 412 may control loop parameters to set the bandwidth for the PLL.

In some aspects, the signal processing circuit subtracts, via a second combiner (e.g., combiner 804), a second jitter detection signal from the first jitter detection signal to yield a third jitter detection signal. The analog jitter detection signal may be generated based on the third jitter detection signal. The second jitter detection signal may be from a jitter detection circuit.

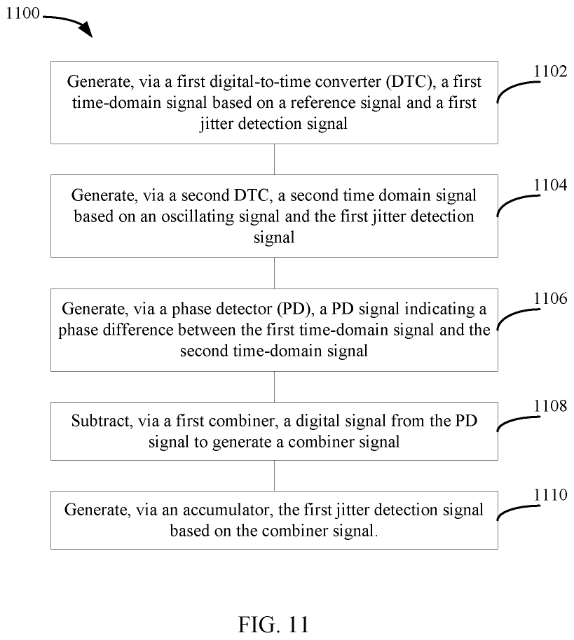

FIG. 11 is a flow diagram depicting example operations 1100 for signal processing, in accordance with certain aspects of the present disclosure. For example, the operations 1100 may be performed by a signal processing circuit, such as the jitter detection circuit 700, and in some aspects, the PLL 400.

At block 1102, the signal processing circuit generates, via a first DTC (e.g., DTC 702), a first time-domain signal based on a reference signal and a first jitter detection signal. At block 1104, the signal processing circuit generates, via a second DTC (e.g., DTC 704), a second time domain signal based on an oscillating signal and the first jitter detection signal. Generating the first time-domain signal may include delaying the reference signal based on the first jitter detection signal, and generating the second time-domain signal includes delaying the oscillating signal based on the first jitter detection signal.

At block 1106, the signal processing circuit generates, via a PD (e.g., PD 706), a PD signal indicating a phase difference between the first time-domain signal and the second time-domain signal. At block 1108, the signal processing circuit subtracts, via a first combiner, a digital signal from the PD signal to generate a combiner signal. The digital signal subtracted from the PD signal may include a fractional digital value.

At block 1110, the signal processing circuit generates, via an accumulator, the first jitter detection signal based on the combiner signal. In some aspects, the signal processing circuit controls at least one of a gain associated with a PD of the PLL or a gain associated with an oscillator of the PLL or the transfer function associated with a low-pass filter of the PLL, based on the jitter detection signal. For example, the loop BW controller 412 may control loop parameters to set a bandwidth for the PLL.

In some aspects, the signal processing circuit subtracts, via a second combiner (e.g., combiner 904), a second jitter detection signal generated by another jitter detection circuit from the first jitter detection signal to generate a third jitter detection signal, the first time-domain signal and the second time-domain signal being generated based on the third jitter detection signal.

### Example Aspects

In addition to the various aspects described above, specific combinations of aspects are within the scope of the disclosure, some of which are detailed below:

Aspect 1. A jitter detection circuit, comprising: a comparator having a first input coupled to an input of the jitter detection circuit; a first combiner having an input coupled to an output of the comparator; an accumulator having an input coupled to an output of the first combiner, an output of the accumulator being coupled to an output of the jitter detection circuit; and a digital-to-analog converter (DAC) having an input coupled to the output of the accumulator, an output of the DAC being coupled to a second input of the comparator.

Aspect 2. The jitter detection circuit of aspect 1, wherein the first combiner is configured to subtract a fractional digital value from a digital signal generated by the comparator.

Aspect 3. A phase-locked loop (PLL) comprising the jitter detection circuit of any one of aspects 1-2, the PLL further comprising: a phase detector (PD), wherein an output of the PD is coupled to the input of the jitter detection circuit; a filter having an input coupled to the output of the PD; an oscillator having a control input coupled to an output of the filter; and a frequency divider coupled between an output of the oscillator and an input of the PD.

Aspect 4. The jitter detection circuit of aspect 3, wherein a first input of the PD is configured to receive a reference signal, and wherein a second input of the PD is configured to receive an oscillating signal.

Aspect 5. A phase-locked loop (PLL) comprising the jitter detection circuit of any one of aspects 1-4, the PLL further comprising a loop bandwidth (BW) controller having an input coupled to the output of the jitter detection circuit and at least one of a first output coupled to a control input of a phase detector of the PLL or a second output coupled to a control input of an oscillator of the PLL.

Aspect 6. The jitter detection circuit of any one of aspects 1-5, further comprising a second combiner having a first input coupled to the output of the accumulator, a second input for coupling to an output of another jitter detection circuit, and an output coupled to the input of the DAC.

Aspect 7. The jitter detection circuit of aspect 6, wherein the second combiner is configured to subtract a first jitter detection signal generated by the other jitter detection circuit from a second jitter detection signal at the output of the accumulator.

Aspect 8. A jitter detection circuit, comprising: a first digital-to-time converter (DTC); a second DTC; a phase detector (PD) having a first input coupled to an output of the first DTC and a second input coupled to an output of the second DTC; a first combiner having an input coupled to an output of the PD; and an accumulator having an input coupled to an output of the first combiner, wherein an output of the accumulator is coupled to a first input of the first DTC and to a first input of the second DTC.

Aspect 9. The jitter detection circuit of aspect 8, wherein the first combiner is configured to subtract a fractional digital value from a digital signal generated by the PD.

Aspect 10. The jitter detection circuit of any one of aspects 8-9, wherein: a second input of the first DTC is configured to receive a reference signal; and a second input of the second DTC is configured to receive an oscillating signal.

Aspect 11. The jitter detection circuit of aspect 10, wherein: the first DTC is configured to generate a first time domain signal by delaying the reference signal based on the digital output signal from the accumulator; and the second DTC is configured to generate a second time domain signal by delaying the oscillating signal based on the digital output signal from the accumulator.

Aspect 12. The jitter detection circuit of any one of aspects 8-11, wherein the PD comprises a bang-bang PD (BBPD).

Aspect 13. A phase-locked loop (PLL) comprising the jitter detection circuit of any one of aspects 8-12, the PLL further comprising a loop bandwidth (BW) controller having an input coupled to the output of the jitter detection circuit and at least one of a first output coupled to a control input of an oscillator of the PLL, a second output coupled to a control input of another PD of the PLL, or a third output coupled to a filter of the PLL.

Aspect 14. The jitter detection circuit of any one of aspects 8-13, further comprising a second combiner having a first input coupled to the output of the accumulator, a second input for coupling to an output of another jitter detection circuit, and an output coupled to the first input of the first DTC and to the second input of the second DTC.

Aspect 15. The jitter detection circuit of aspect 14, wherein the second combiner is configured to subtract a first jitter detection signal generated by the other jitter detection circuit from a second jitter detection signal at the output of the accumulator.

Aspect 16. A method for signal processing, comprising: comparing, via a comparator, a phase detector (PD) output voltage and an analog jitter detection signal to yield a comparator output signal; subtracting, via a first combiner, a digital signal from the comparator output signal; accumulating, via an accumulator, an output signal from the first combiner to generate a first jitter detection signal; and generating, via a digital-to-analog converter (DAC), the analog jitter detection signal based on the first jitter detection signal.

Aspect 17. The method of aspect 16, wherein the digital signal subtracted from the comparator output signal comprises a fractional digital value.

Aspect 18. The method of any one of aspects 16-17, wherein the PD output voltage represents a difference between a phase of a reference signal and a phase of an oscillating signal.

Aspect 19. The method of any one of aspects 16-17, further comprising controlling at least one of a gain associated with a PD of a phase-locked loop (PLL) or a gain associated with an oscillator of the PLL, based on the first jitter detection signal.

Aspect 20. The method of any one of aspects 16-19, further comprising subtracting, via a second combiner, a second jitter detection signal from the first jitter detection signal to yield a third jitter detection signal, wherein the analog jitter detection signal is generated based on the third jitter detection signal and wherein the second jitter detection signal is from a jitter detection circuit.

Aspect 21. A method for signal processing, comprising: generating, via a first digital-to-time converter (DTC), a first time-domain signal based on a reference signal and a first jitter detection signal; generating, via a second DTC, a second time-domain signal based on an oscillating signal and the first jitter detection signal; generating, via a phase detector (PD), a PD signal indicating a phase difference between the first time-domain signal and the second time-domain signal; subtracting, via a first combiner, a digital signal from the PD signal to generate a combiner signal; and generating, via an accumulator, the first jitter detection signal based on the combiner signal.

Aspect 22. The method of aspect 21, wherein the digital signal subtracted from the PD signal comprises a fractional digital value.

Aspect 23. The method of any one of aspects 21-22, wherein: generating the first time-domain signal includes delaying the reference signal based on the first jitter detection signal; and generating the second time-domain signal includes delaying the oscillating signal based on the first jitter detection signal.

Aspect 24. The method of any one of aspects 21-23, further comprising controlling at least one of a gain associated with a PD of a phase-locked loop (PLL) or a gain associated with an oscillator of the PLL, based on the first jitter detection signal.

Aspect 25. The method of any one of aspects 21-24, further comprising subtracting, via a second combiner, a second jitter detection signal generated by a jitter detection circuit from the first jitter detection signal to generate a third jitter detection signal, the first time-domain signal and the second time-domain signal being generated based on the third jitter detection signal.

### ADDITIONAL CONSIDERATIONS

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another-even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

The apparatus and methods described in the detailed description are illustrated in the accompanying drawings by various blocks, modules, components, circuits, steps, processes, algorithms, etc. (collectively referred to as “elements”). The various operations or methods described above may be performed by any suitable means capable of performing the corresponding functions. The means may include various hardware and/or software component(s) and/or module(s), including, but not limited to a circuit, an application specific integrated circuit (ASIC), or processor. Generally, where there are operations illustrated in figures, those operations may have corresponding counterpart means-plus-function components with similar numbering.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

It is to be understood that the claims are not limited to the precise configuration and components illustrated above. Various modifications, changes and variations may be made in the arrangement, operation and details of the methods and apparatus described above without departing from the scope of the claims.

1. A jitter detection circuit, comprising:
a comparator having a first input coupled to an input of the jitter detection circuit;
a first combiner having an input coupled to an output of the comparator;
an accumulator having an input coupled to an output of the first combiner, an output of the accumulator being coupled to an output of the jitter detection circuit; and
a digital-to-analog converter (DAC) having an input coupled to the output of the accumulator, an output of the DAC being coupled to a second input of the comparator.

2. The jitter detection circuit of claim 1, wherein the first combiner is configured to subtract a fractional digital value from a digital signal generated by the comparator.

3. A phase-locked loop (PLL) comprising the jitter detection circuit of claim 1, the PLL further comprising:
a phase detector (PD), wherein an output of the PD is coupled to the input of the jitter detection circuit;
a filter having an input coupled to the output of the PD;
an oscillator having a control input coupled to an output of the filter; and
a frequency divider coupled between an output of the oscillator and an input of the PD.

4. The jitter detection circuit of claim 3, wherein a first input of the PD is configured to receive a reference signal, and wherein a second input of the PD is configured to receive an oscillating signal.

5. A phase-locked loop (PLL) comprising the jitter detection circuit of claim 1, the PLL further comprising a loop bandwidth (BW) controller having an input coupled to the output of the jitter detection circuit and at least one of a first output coupled to a control input of a phase detector of the PLL or a second output coupled to a control input of an oscillator of the PLL.

6. The jitter detection circuit of claim 1, further comprising a second combiner having a first input coupled to the output of the accumulator, a second input for coupling to an output of another jitter detection circuit, and an output coupled to the input of the DAC.

7. The jitter detection circuit of claim 6, wherein the second combiner is configured to subtract a first jitter detection signal generated by the other jitter detection circuit from a second jitter detection signal at the output of the accumulator.

8. A jitter detection circuit, comprising:
a first digital-to-time converter (DTC);
a second DTC;
a phase detector (PD) having a first input coupled to an output of the first DTC and a second input coupled to an output of the second DTC;
a first combiner having an input coupled to an output of the PD; and
an accumulator having an input coupled to an output of the first combiner, wherein an output of the accumulator is coupled to a first input of the first DTC and to a first input of the second DTC.

9. The jitter detection circuit of claim 8, wherein the first combiner is configured to subtract a fractional digital value from a digital signal generated by the PD.

10. The jitter detection circuit of claim 8, wherein:
a second input of the first DTC is configured to receive a reference signal; and
a second input of the second DTC is configured to receive an oscillating signal.

11. The jitter detection circuit of claim 10, wherein:
the first DTC is configured to generate a first time domain signal by delaying the reference signal based on the digital output signal from the accumulator; and
the second DTC is configured to generate a second time domain signal by delaying the oscillating signal based on the digital output signal from the accumulator.

12. The jitter detection circuit of claim 8, wherein the PD comprises a bang-bang PD (BBPD).

13. A phase-locked loop (PLL) comprising the jitter detection circuit of claim 8, the PLL further comprising a loop bandwidth (BW) controller having an input coupled to the output of the jitter detection circuit and at least one of a first output coupled to a control input of an oscillator of the PLL, a second output coupled to a control input of another PD of the PLL, or a third output coupled to a filter of the PLL.

14. The jitter detection circuit of claim 8, further comprising a second combiner having a first input coupled to the output of the accumulator, a second input for coupling to an output of another jitter detection circuit, and an output coupled to the first input of the first DTC and to the second input of the second DTC.

15. The jitter detection circuit of claim 14, wherein the second combiner is configured to subtract a first jitter detection signal generated by the other jitter detection circuit from a second jitter detection signal at the output of the accumulator.

16. A method for signal processing, comprising:
comparing, via a comparator, a phase detector (PD) output voltage and an analog jitter detection signal to yield a comparator output signal;
subtracting, via a first combiner, a digital signal from the comparator output signal;
accumulating, via an accumulator, an output signal from the first combiner to generate a first jitter detection signal; and
generating, via a digital-to-analog converter (DAC), the analog jitter detection signal based on the first jitter detection signal.

17. The method of claim 16, wherein the digital signal subtracted from the comparator output signal comprises a fractional digital value.

18. The method of claim 16, wherein the PD output voltage represents a difference between a phase of a reference signal and a phase of an oscillating signal.

19. The method of claim 16, further comprising controlling at least one of a gain associated with a PD of a phase-locked loop (PLL) or a gain associated with an oscillator of the PLL, based on the first jitter detection signal.

20. The method of claim 16, further comprising subtracting, via a second combiner, a second jitter detection signal from the first jitter detection signal to yield a third jitter detection signal, wherein the analog jitter detection signal is generated based on the third jitter detection signal and wherein the second jitter detection signal is from a jitter detection circuit.

21. A method for signal processing, comprising:
generating, via a first digital-to-time converter (DTC), a first time-domain signal based on a reference signal and a first jitter detection signal;
generating, via a second DTC, a second time-domain signal based on an oscillating signal and the first jitter detection signal;
generating, via a phase detector (PD), a PD signal indicating a phase difference between the first time-domain signal and the second time-domain signal;
subtracting, via a first combiner, a digital signal from the PD signal to generate a combiner signal; and
generating, via an accumulator, the first jitter detection signal based on the combiner signal.

22. The method of claim 21, wherein the digital signal subtracted from the PD signal comprises a fractional digital value.

23. The method of claim 21, wherein:
generating the first time-domain signal includes delaying the reference signal based on the first jitter detection signal; and
generating the second time-domain signal includes delaying the oscillating signal based on the first jitter detection signal.

24. The method of claim 21, further comprising controlling at least one of a gain associated with a PD of a phase-locked loop (PLL) or a gain associated with an oscillator of the PLL, based on the first jitter detection signal.

25. The method of claim 21, further comprising subtracting, via a second combiner, a second jitter detection signal generated by a jitter detection circuit from the first jitter detection signal to generate a third jitter detection signal, the first time-domain signal and the second time-domain signal being generated based on the third jitter detection signal.
